(19) United States
(12) Patent Application Publication
(10) Pub. No.: US 2009/0305471 A1
(43) Pub. Date: Dec. 10, 2009

(54) THIN SILICON SINGLE DIFFUSION FIELD EFFECT TRANSISTOR FOR ENHANCED DRIVE PERFORMANCE WITH STRESS FILM LINERS

(75) Inventors: Leland Chang, New York, NY (US); David M. Fried, Ithaca, NY (US); John M. Hergenrother, Ridgefield, CT (US); Ghavam Shahidi, Pound Ridge, NY (US); Jeffrey W. Sleight, Ridgefield, CT (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 12/541,605

(22) Filed: Aug. 14, 2009

Related U.S. Application Data
(62) Division of application No. 11/329,490, filed on Jan. 11, 2006.

(51) Int. Cl. H01L 21/762; H01L 21/8238; H01L 21/336

(52) U.S. Cl. 438/154; 438/151; 257/E21.632; 257/E21.409; 257/E21.561

(57) ABSTRACT

The present invention provides a semiconducting device structure including a thin SOI region, wherein the SOI device is formed with an optional single thin diffusion, i.e., offset, spacer and a single diffusion implant. The device silicon thickness is thin enough to permit the diffusion implants to abut the buried insulator but thick enough to form a contacting silicide. Stress layer liner films are used both over nFET and pFET device regions to enhance performance.

### CROSS REFERENCE TO RELATED APPLICATION

This application is a divisional application of U.S. Ser. No. 11/329,490 filed on Jan. 11, 2006 entitled “THIN SILICON SINGLE DIFFUSION FIELD EFFECT TRANSISTOR FOR ENHANCED DRIVE PERFORMANCE WITH STRESS FILM LINERS”. The entire content of of the aforementioned U.S. application is incorporated herein.

### FIELD OF THE INVENTION

The present invention relates to semiconductor devices, and more particularly to integrated semiconductor devices, such as complementary metal oxide semiconductor (CMOS) devices, located atop a substrate having a thin (on the order of about 50 nm or less) semiconductor-on-insulator (SOI) layer. In particular, the present invention forms nFET (field effect transistor) and pFET devices on the thin SOI layer. In additional to being located on a thin SOI layer, the FET devices of the present invention include an optional single ultra-thin diffusion spacer, a single diffusion junction, and dual stress film liners. Dual stress film liners have been described previously in the art, and usually incorporate one stress film type (typically tensile) to enhance nFET drive current performance and another stress film type (typically compressive) to enhance pFET drive current performance.

### BACKGROUND OF THE INVENTION

Semiconductor-on-insulator (SOI) devices, particularly silicon-on-insulator devices, offer several advantages over more conventional semiconductor devices. For example, SOI devices may have lower power consumption requirements than other types of devices that perform similar tasks. SOI devices may also have lower parasitic capacitances than non-SOI devices. This translates into faster switching times for the resulting circuits. In addition, the phenomenon of “latchup”, which is often exhibited by complementary metal-oxide semiconductor (CMOS) devices, maybe avoided when circuit devices are manufactured using SOI fabrication processes. SOI devices are also less susceptible to the adverse effects of ionizing radiation and, therefore, tend to be more reliable in applications where ionizing radiation may cause operation errors.

A recent innovation, dual stress liner films, enhances both nFET and pFET drive currents. This is reported, for example, in IEDM 2004, H. S. Yang et al, “Dual Stress Liner for High Performance sub-45 nm Gate Length CMOS SOI Manufacturing”. It is well known that covering an nFET device with a tensile film (typically silicon nitride) and that covering a pFET device with a compressive film (again, typically silicon nitride) that the device channel regions are under stress that alters the band structure and enhances the electron and hole mobilities, respectively.

There are several process integration methods for the creation of dual stress films. The underlying theme is the blanket deposition of a first stress layer type, followed by lithography to mask and protect this first stress layer type, an etch to remove the first stress layer type where it is not desired, and then deposition of the second stress layer type. The resulting enhanced carrier mobility, in turn, leads to higher FET drive currents and therefore higher circuit level performance.

Also, there are several known advantages in scaling the SOI device film thickness (from a typical value of about 70 to about 200 nm) to thinner values (typically less than 50 nm). These include a lower diffusion junction capacitance, better short channel characteristics, and also, in the case of a technology using either single or dual stress liner films, higher amounts of stress imparted to the device channel. The higher levels of stress will, in turn, enhance the drive current performance of these FETs even further.

To date, there is no known prior art that combines the use of a thin SOI layer (having a thickness of about 50 nm or less) with dual stress liners in providing a field effect transistor that has enhanced drive current performance.

### SUMMARY OF THE INVENTION

One object of the present invention is to provide a semiconductor device that includes at least one field effect transistor (FET) on an SOI layer having a thickness of less than 50 nm. The term “SOI substrate” is used herein to denote a semiconductor-on-insulator substrate that includes an upper semiconductor layer and a lower semiconductor layer that are separated by a buried insulating layer. The SOI layer, which represents the upper layer of the SOI substrate, is the layer in which the FETs will be formed.

Another object of the present invention is to provide a semiconductor device that includes single diffusion regions and an optional single ultra-thin diffusion, e.g., offset, spacer. The offset spacer is typically comprised of silicon oxide or silicon nitride and the total lateral dimension from the gate edge is from about 3 to about 20 nm, with a value of about 10 to about 15 nm being even more typical.

A further object of the invention is to incorporate dual pre-doping for the gate electrode in the case where the gate electrode is composed of polysilicon.

A yet further object of the present invention is to provide a semiconductor device that includes field effect transistors (FETs) on a SOI layer having a device channel that is under mechanical stress from an overlying stress film layer (typically silicon nitride). The stress film layer is tensile for nFETs and compressive for pFETs. The level of stress is typically in a range from about 1 to about 10 GPa.

An even further object of the present invention is to reduce the offset spacer dimension to below 3 nm or to eliminate them completely, maximizing the stress imparted to the channel. In this embodiment of the present invention, the diffusion junction are annealed, i.e., activated, using an advanced annealing technique, such as, a laser anneal, to avoid high levels of dopant diffusion into the channel and to avoid the poor short channel characteristics that would occur.

A further object of the present invention is to thin the SOI layer even further to a range from about 5 to about 15 nm. In this range, either an ultra-thin silicide would be required, or no silicide at all. Higher contact resistance could be tolerated in some CMOS applications, such as high-density logic static random access memory (SRAM) arrays and in certain low power applications.

In broad terms, the present invention provides a semiconductor structure that includes:

a semiconductor-on-insulator (SOI) substrate including at least an upper semiconductor layer having a device channel thickness of less than 50 nm;

at least one field effect transistor (FET) located on said upper semiconductor layer, said at least one FET including single, continuous diffusion regions whose junctions depths are the same as said device channel thickness; and

a stressed liner located atop said at least one FET and said SOI substrate which transfers stress to a channel of the at least one FET.

In accordance with the present invention, the at least one FET can comprise a pFET or a plurality thereof, an nFET or a plurality thereof, of combination of a pFET and an nFET or a plurality of said different polarity FETs. In embodiments in which pFETs and nFETs are both present, dual stress film liners are used. In such an embodiment, a stress liner under tensile strain is located atop the nFETs, while a stress liner under compressive strain is located atop the pFETs.

In some embodiments, of the present invention, a single diffusion spacer (i.e., offset spacer) is present on the sidewalls of the FET. The single diffusion spacer employed in the present invention is an ultra-thin spacer having a lateral dimension from about 3 to about 20 nm. In some embodiments, the single diffusion spacer can be scaled to below 3 nm or even eliminated when an advanced thermal process is used for activating the single, continuous diffusion regions.

In some embodiments of the present invention, a silicide contact can be located in the upper semiconductor layer adjoining the at least one FET. When the silicide contact is present, it may have a thickness that is about 10 nm or less.

In yet another embodiment of the present invention, the at least one FET includes a pFET and an nFET which share a common contacted or uncontacted single, continuous diffusion region.

It is noted that the term “single, continuous diffusion region(s)” denotes diffusion regions which are made from a single ion implantation step. In particular and because of the thinness of the SOI layer, the single, continuous diffusion regions are formed utilizing an extension ion implantation step only. No deep source/drain implantation step, typically used in fabricating conventional FETs, is used in the present invention.

In addition to the semiconductor structure, the present invention also provides a method of fabricating such a structure. In broad terms, the method of the present invention comprises:

providing a semiconductor-on-insulator (SOI) substrate having at least an upper semiconductor layer with a device channel thickness of less than 50 nm;

forming at least one patterned gate region on a surface of said SOI substrate;

implanting single, continuous diffusion regions on opposing sides of said at least one patterned gate region; and

forming a stressed liner atop said at least one patterned gate region and said SOI substrate which transfers stress to a device channel located between the single, continuous diffusion regions and underneath the at least one patterned gate region.

In accordance with the present invention, the at least one patterned gate region, which includes a gate dielectric and a gate conductor, can comprise a pFET or a plurality thereof, an nFET or a plurality thereof, of combination of a pFET and an nFET or a plurality of said different polarity FETs. In embodiments in which pFETs and nFETs are both present, dual stress film liners are used. In such an embodiment, a stress liner under tensile strain is located atop the nFETs, while a stress liner under compressive strain is located atop the pFETs.

In some embodiments, of the present invention, a single diffusion spacer (i.e., offset spacer) is formed on the sidewalls of the at least one patterned gate region. The single diffusion spacer employed in the present invention is an ultra-thin spacer having a lateral dimension from about 3 to about 20 nm. In some embodiments, the single diffusion spacer can be scaled to below 3 nm or even eliminated when an advanced thermal process is used for activating the single, continuous diffusion regions.

In some embodiments of the present invention, a silicide contact can be formed in the upper semiconductor layer adjoining the at least one patterned gate region. When the silicide contact is present, it may have a thickness that is about 10 nm or less.

### BRIEF DESCRIPTION OF THE DRAWINGS

FIGS. 1A-1F are pictorial representations (through cross sectional views) illustrating the basic processing steps used in the present invention.

FIG. 2 is a pictorial representation (through cross sectional view) illustrating the FET device structure of the present invention with the dual stress liner integration approach with both FET types present.

### DETAILED DESCRIPTION OF THE INVENTION

The present invention, which provides a thin silicon single diffusion FET for enhanced drive current performance with stress liners, will now be described in greater detail by referring to the following discussion as well as the drawings that accompany the present application. In the accompanying drawings, like and correspondence elements are referred to by like reference numerals. It is noted that the drawings of the present application are provided for illustrative purposes and thus they are not drawn to scale.

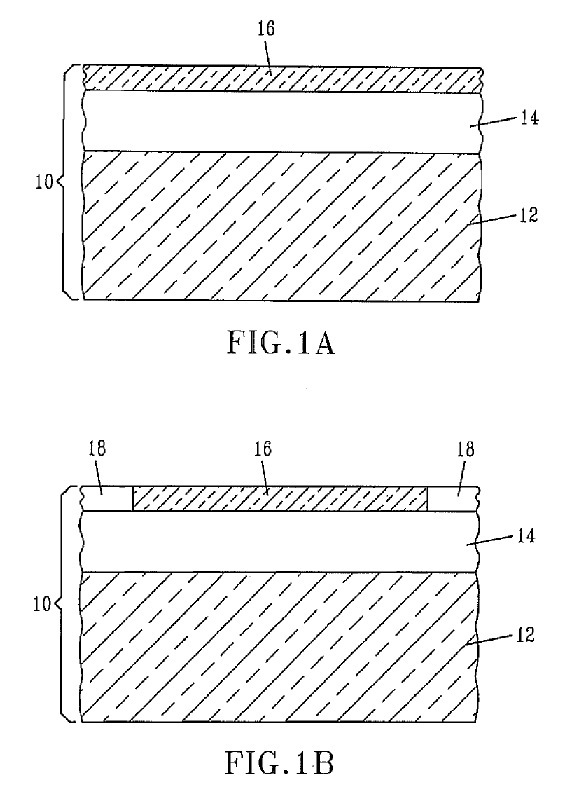

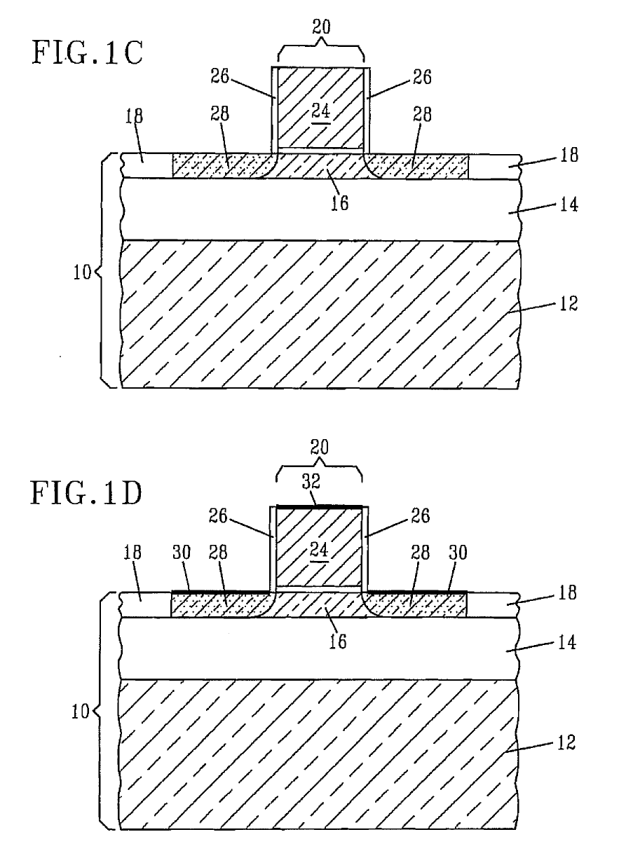

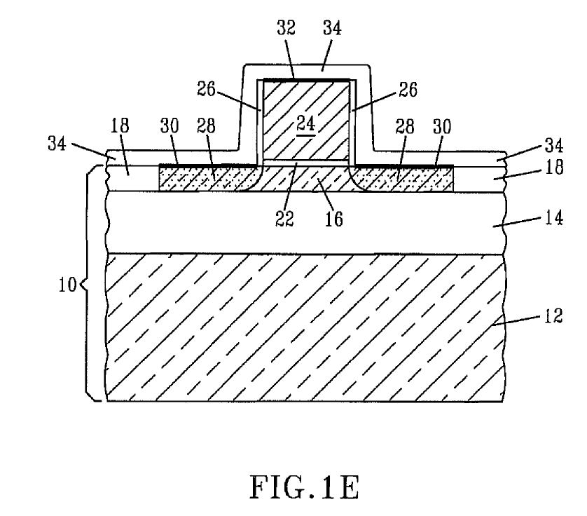

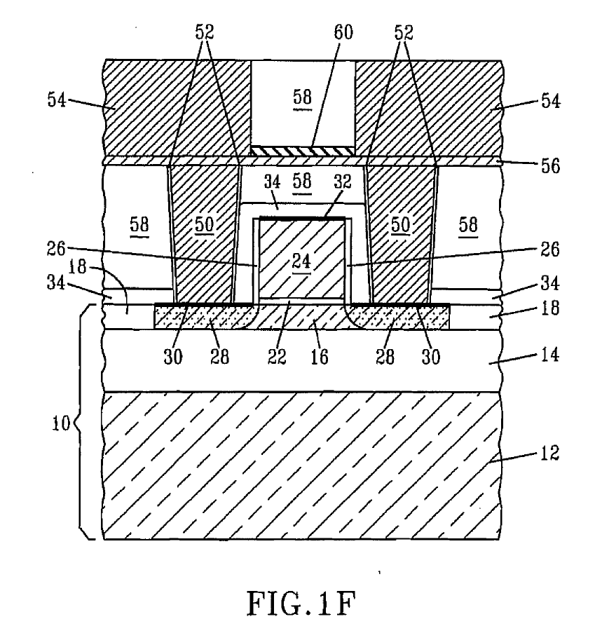

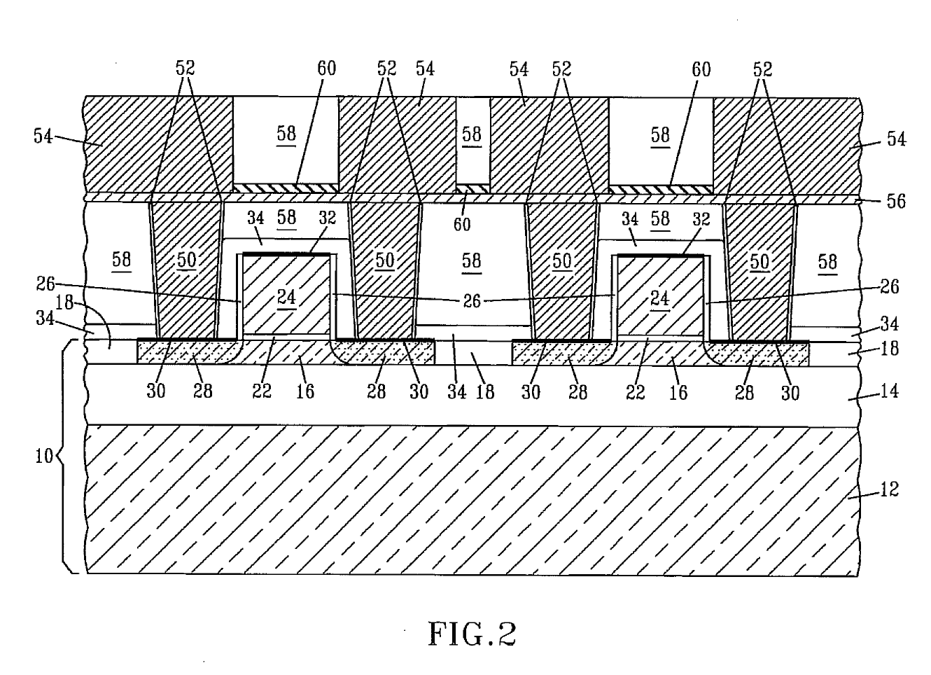

The present invention will now be described in detail by first referring to FIGS. 1A-1F which are cross sectional views illustrating the basic processing steps of the present invention. In this embodiment, a single FET device is shown. Although a single FET device is shown and illustrated, the present invention also works equally well when a plurality of FETs are formed. In embodiments in which a plurality of FETs are formed, the FETs may have the same polarity (nFETs or pFETs) or they may comprise a combination of at least one nFET and at least one pFET. The latter embodiment, which is depicted in FIG. 2, will be described after the general description concerning FIGS. 1A-1F.

FIG. 1A illustrates the initial SOI substrate 10 that is employed in the present invention. The initial SOI substrate 10 includes a bottom semiconductor layer 12 and an upper semiconductor layer, e.g., the SOI layer, 16 that are separated by a buried insulating layer 14. The SOI substrate 10 can be formed utilizing conventional techniques well known in the art. For example, the initial SOI substrate 10 can be formed by ion implantation into a semiconductor substrate followed by annealing. Typically, the ions are oxygen ions and a technique referred to as SIMOX (separation by ion implantation of oxygen) is used in forming the SOI substrate. Alternatively, the SOI substrate 10 can be formed by a layer transfer process in which bonding of two semiconductor layers takes place.

The buried insulating layer 14 of the initial SOI substrate 10 comprises a crystalline or non-crystalline oxide, nitride, oxynitride or any other insulating material. The buried insulating layer 14 of the initial SOI substrate typically has a thickness from about 5 nm to about 500 nm, with a thickness from about 50 nm to about 200 nm being more typical. The buried insulating layer 14 may be continuous or it may be a discrete region, i.e., an island.

The semiconductor layers 12 and 16 are comprised of the same or different semiconducting material including, for example, Si, SiC, SiGe, SiGeC, Ge alloys, GaAs, InAs, InP as well as other III-V or II-VI compound semiconductors. Typically, semiconductor layers 12 and 16 are Si-containing semiconductors such as Si or SiGe. The semiconductor layers 12 and 16 may have the same or different crystal orientation including, for example, (100), (110) or (111). The semiconductor layers 12 and 16 can be unstrained, strained or contained a combination of strained and unstrained regions therein.

The thickness of the bottom semiconductor layer 12 may vary and is not critical for practicing the present invention. The initial thickness of the upper semiconductor layer 16 may vary depending on the technique used in forming the same. If the upper semiconductor layer 16 is not less than 50 nm, it maybe thinned to the desired thickness of less than 50 nm by planarization, grinding, wet etching, dry etching or any combination thereof. In a preferred embodiment, the upper semiconductor layer 16 is thinned by oxidation and wet etching to achieve the desired thickness of less than 50 nm. Note that in the present invention, the FETs are built upon an upper semiconductor layer 16 that is less than 50 nm, preferably from about 5 to about 25 nm. The thickness of the upper SOI layer 16 determines the device channel thickness of the present invention.

Next, and as also shown in FIG. 1B, an isolation region 18, such as a shallow trench isolation region, is typically formed so as to isolate one SOI device region from another SOI device region. The isolation region 18 is formed utilizing processing steps that are well known to those skilled in the art including, for example, trench definition and etching, optionally lining the trench with a diffusion barrier, and filling the trench with a trench dielectric such as an oxide. After the trench fill, the structure may be planarized and an optional densification process step may be performed to densify the trench dielectric. The isolation region 18 may or may not contact the buried insulating layer 14. In the drawings, isolation region 18 contacts the buried insulating layer 14.

After forming the isolation region 18, the upper semiconductor layer 16 is processed forming an SOI device region. The SOI device region is typically located in the upper semiconductor layer 16 and it typically is in an area between two isolation regions. Specifically, the SOI device region is processed utilizing conventional block mask techniques. A block mask that can be used in the present invention in forming the SOI device region can comprise a conventional soft and/or hard mask material and it can be formed using deposition, photolithography and etching In a preferred embodiment, the block mask comprises a photoresist. A photoresist block mask can be produced by applying a blanket photoresist layer to the substrate surface, exposing the photoresist layer to a pattern of radiation, and then developing the pattern into the photoresist layer utilizing conventional resist developer.

Alternatively, the block mask can be a hard mask material. Hard mask materials include dielectrics that may be deposited by chemical vapor deposition (CVD) and related methods. Typically, the hard mask composition includes silicon oxides, silicon carbides, silicon nitrides, silicon carbonitrides, etc. Spin-on dielectrics may also be utilized as a hard mask material including but not limited to: silsesquioxanes, siloxanes, and boron phosphate silicate glass (BPSG).

The SOI device region may be formed by selectively implanting p-type or n-type dopants into the semiconductor layer 16. It is noted that the n-type device region is typically used when a pFET channel is to be subsequently formed, while a p-type device region is typically used when an nFET channel is to be subsequently formed.

The surface of SOI substrate 10 is typically cleaned at this point of the inventive process to remove any residual layers (e.g., native oxide), foreign particles, and any residual metallic surface contamination and to temporarily protect the cleaned substrate surface. Any residual silicon oxide is first removed in a solution of hydrofluoric acid. The preferred removal of particles and residual metallic contamination is based on the industry standard gate dielectric preclean known as RCA clean. The RCA clean includes a treatment of the SOI substrate 10 in a solution of ammonium hydroxide (NH₄OH) and hydrogen peroxide (H₂O₂) followed by an aqueous mixture of hydrochloric acid and an oxidizing agent (e.g., H₂O₂, O₃). As a result, the cleaned substrate surface is sealed with a very thin layer of chemical oxide (not shown). While the protective chemical oxide is typically made thinner than about 10 Å so to not interfere with the properties of gate dielectric 22 (to be subsequently formed), its thickness can be varied to beneficially alter properties of the gate dielectric 22.

A blanket layer of gate dielectric 22 is formed on the entire surface of the SOI substrate 10 including the atop the isolation region 18, if it is a deposited dielectric. The gate dielectric 22 can be formed by a thermal growing process such as, for example, oxidation. Alternatively, the gate dielectric 22 can be formed by a deposition process such as, for example, chemical vapor deposition (CVD), plasma-assisted CVD, atomic layer or pulsed deposition (ALD or ALPD), evaporation, reactive sputtering, chemical solution deposition or other like deposition processes. The gate dielectric 22 may also be formed utilizing any combination of the above processes.

The gate dielectric 22 is comprised of an insulating material having a dielectric constant of about 4.0 or greater, preferably greater than 7.0. The dielectric constants mentioned herein are relative to a vacuum, unless otherwise stated. Note that SiO₂ typically has a dielectric constant that is about 4.0. Specifically, the gate dielectric 22 employed in the present invention includes, but is not limited to: an oxide, nitride, oxynitride and/or silicates including metal silicates, aluminates, titanates and nitrides. In one embodiment, it is preferred that the gate dielectric 22 is comprised of an oxide such as, for example, SiO₂, HfO₂, ZrO₂, Al₂O₃, TiO₂, La₂O₃, SrTiO₃, LaAlO₃, Y₂O₃ and mixtures thereof.

The physical thickness of the gate dielectric 22 may vary, but typically, the gate dielectric 22 has a thickness from about 0.5 to about 10 nm, with a thickness from about 0.5 to about 2 nm being more typical.

After forming the gate dielectric 22, a blanket layer of polysilicon or another gate conductor material or combination thereof, which becomes the gate conductor 24 shown in FIG. 1C, is formed on the gate dielectric 22 utilizing a known deposition process such as, for example, physical vapor deposition, CVD or evaporation. The blanket layer of gate conductor material may be doped or undoped. If doped, an in-situ doping deposition process may be employed in forming the same. Alternatively, a doped gate conductor layer can be formed by deposition, ion implantation and annealing. The doping of the gate conductor layer will shift the workfunction of the gate formed. Illustrative examples of dopant ions include As, P, B, Sb, Bi, In, Al, Ga, TI or mixtures thereof. Typical doses for the ion implants are 1E14 (=1×10¹⁴) to 1E16 (=1×10¹⁶) atoms/cm² or more typically 1E15 to 5E15 atoms/cm². The thickness, i.e., height, of the gate conductor 24 deposited at this point of the present invention may vary depending on the deposition process employed. Typically, the gate conductor 24 has a vertical thickness from about 20 to about 180 nm, with a thickness from about 40 to about 150 nm being more typical.

The gate conductor 24 can comprise any conductive material that is typically employed as a gate of a CMOS structure. Illustrative examples of such conductive materials that can be employed as the gate conductor 24 include, but are not limited to: polysilicon, conductive metals or conductive metal alloys, conductive silicides, conductive nitrides, polySiGe and combinations thereof, including multilayers thereof. In some embodiments, it is possible to form a barrier layer between multiple layers of gate conductors.

An optional dielectric cap (not shown) such as an oxide or nitride can be optionally formed atop the gate conductor 24 at this point of the present invention. The optional dielectric cap is typically removed before or immediately after the single, continuous diffusion regions to be subsequently formed have been silicided. A conventional deposition process such as CVD or PECVD can be used in forming the optional dielectric cap. When present, the optional dielectric cap has a thickness from about 10 to about 50 nm.

The blanket gate conductor 24, the gate dielectric 22 and optionally the dielectric cap are then patterned by lithography and etching so as to provide at least one patterned gate region 20. The structure including the at least one patterned gate region 20 is shown in FIG. 1C. When a plurality of patterned gate regions are present, the patterned gate regions may have the same

dimension, i.e., length, or they can have variable dimensions to improve device performance. Each patterned gate region at this point of the present invention includes at least a stack of the gate conductor 24 and the gate dielectric 22. The lithography step includes applying a photoresist to the upper surface of the gate conductor 24, exposing the photoresist to a desired pattern of radiation and developing the exposed photoresist utilizing a conventional resist developer. The pattern in the photoresist is then transferred to the blanket layer of gate conductor 24 and the gate dielectric 22 utilizing one or more dry etching steps. In some embodiments, the patterned photoresist may be removed after the pattern has been transferred into the blanket layer of gate conductor 24. When an optional dielectric cap is present, the photoresist is applied to the cap and the above processing is performed.

Suitable dry etching processes that can be used in the present invention in forming the patterned gate regions 20 include, but are not limited to: reactive-ion etching, ion beam etching, plasma etching or laser ablation. A wet or dry etching process can also be used to remove portions of the gate dielectric 22 that are not protected by the patterned gate conductor 24.

Next, an offset spacer (i.e., diffusion spacer) 26 is typically, but not necessarily, formed on exposed sidewalls of each patterned gate region 20. The offset spacer 26 is comprised of an insulator such as an oxide, nitride, oxynitride, or carbon-containing silicon oxide, nitride, oxynitride, and/or any combination thereof. Preferably, the offset spacer 26 is comprised of an oxide or an oxynitride. The offset spacer 26 can be formed by deposition and etching or by thermal techniques. The width of the offset spacer 26, as measured at the surface of the SOI substrate 10, is narrower than conventional spacers that are used in forming deep source/drain regions. The width of the offset spacer 26 formed may be adjusted to compensate for different diffusion rates of p-type dopants and n-type dopants which are used in forming the single, continuous diffusion regions 28. Typically, the offset spacer 26 have a lateral width from about 3 to about 20 nm, with a lateral width from about 7 to about 15 nm being even more typical. In some embodiments, the width of the offset spacer 26 can be scaled below 3 nm or even eliminated if an advanced thermal process such as a laser anneal is used in activating the dopants within the single, continuous diffusion regions 28.

Next, the single, continuous diffusion regions 28 are formed utilizing a conventional extension ion implantation process. The single, continuous diffusion regions 28 can be formed in the presence or the absence of the offset spacer 26. The single, continuous diffusion regions 28 which form the source/drain regions of the FET device have a junction depth that is less than 50 nm, i.e., within the desired thickness of the SOI layer 16. It is noted that the single, continuous diffusion regions 28 could be considered as extension regions in a conventional FET since their depth is much shallower than that of deep source/drain regions. As shown (See FIG. 1C), the single, continuous diffusion regions 28 are present on each side of the patterned gate region 20 at the footprint thereof. The region between the diffusion regions 28 directly beneath the patterned gate region 20 is the device channel 30.

After the implantation of the single, continuous diffusion regions 28, the diffusion regions 28 are activated using a conventional annealing process such as a finance anneal or a rapid thermal anneal. The conventional thermal annealing is typically used in conjunction with the offset spacer 26. In other embodiments, an advance activation anneal such as, a laser anneal, is used. When advanced annealing is used to activate the diffusion regions 28, the offset spacer 26 can be scaled below 3 nm or even eliminated.

A halo implant may be performed at this point of the present invention utilizing a conventional halo ion implantation process. Although a halo ion implantation can be used, it does not represent the formation of another diffusion regions within the SOI layer 16. As such, the SOI layer 16 of the present invention only includes the single, continuous diffusion regions 28. The structure including the single, diffusion regions 28 and offset spacer 26 is shown in FIG. 1C. Alternatively, for device silicon thickness under 10 nm a halo implant is not typically required as the deive threshold voltage becomes controlled more strongly by the gate electrode.

FIG. 1D shows the structure after silicidation of at least the exposed portions of the SOI layer 16 that includes the single, continuous diffusion regions 28 which forms silicide contacts 30. In some embodiments, a silicide contact 32 is formed atop the gate conductor 24. The formation of silicide contacts 30 and 32 is optional and includes the use of a standard salicidation (‘self-aligned’) process well known in the art. This includes forming a metal capable of reacting with Si atop the entire structure, forming a barrier layer atop the metal, heating the structure to form a silicide, removing non-reacted metal and the barrier layer and, if needed, conducting a second heating step. The second heating step is required in those instances in which the first heating step does not form the lowest resistance phase of the silicide. In some embodiments, the silicide contacts 30 and 32 have a thickness that is below 10 nm.

FIG. 1E shows the structure after forming a stress-inducing liner 34 over the structure shown in FIG. 1D. The liner 34 is formed by a conventional deposition process such as, for example, chemical vapor deposition, plasma enhanced chemical vapor deposition, chemical solution deposition, evaporation and other like deposition processes. The liner 34 is comprised of a material that is capable of introducing stress into the channel region of the structure. For example, liner 34 may be comprised of a nitride that is under either tensile (for nFETs) an/or compressive stress (for pFETs). The liner 34, when present, typically has a thickness from about 10 to about 1000 nm, with a thickness from about 20 to about 50 nm being even more typical. In cases when both nFETs and pFETs are present, liner 34 may be referred to as a dual liner. This embodiment is shown in FIG. 2. Typical amounts of stress than can be achieved are in the range from about 1 to about 10 GPa, with a range from about 2 to about 5 GPa being even more typical. Different types (tensile and compressive) and amounts of stress are controlled by process details of stress layer deposition, such as temperature, pressure and film layer thickness. Dual liners are formed utilizing processing techniques well known in the art such as, for example, lithography with a soft or hard mask, etching and liner deposition.

FIG. 1F (as well as FIG. 2) shows the structure through conventional back-end-of-the-line (BEOL), i.e., interconnect, processing. Specifically, FIG. 1F (and FIG. 2) show the structure including diffusion contacts 50, contact liners 52, metal region 54, metal liner 56, metal and contact dielectric 58, and a contact/metal dielectric barrier 60. A contact to the gate stack (not shown) may also be formed. It is again emphasized that the processing of elements 50, 52, 54, 56, 58 and 60 are well known in the art and, as such, no further details are required.

When FETs of different conductivities are formed, the processing steps mentioned above are generally used in conjunction with block masks. It should be noted that in FIG. 2, the isolation region between the different FETs can be removed such that the two FETs share a common single, continuous diffusion region.

Although specific mention of the above processing is made, the present invention can also be implemented into a replacement gate process by first providing the structure shown in FIG. 1C by a conventional replacement gate process and then following the description provided for FIGS. 1D-1F. When a replacement gate process is used, the offset spacers can be formed prior to forming the gate regions or after forming the gate regions.

It is noted by eliminating the usual requirement for a diffusion implant spacer the present invention provides a means for forming high-density logic devices, such as static random access memory (SRAM) arrays. That is, the present invention provides a dense cell layout wherein each of said semiconductor structures present therein has a gate to gate distance to a neighboring semiconductor structure of about 160 nm or less, compared to a typical pitch of 250 nm or more in a 65 nm technology node. This advantage becomes even more significant in future technology nodes, where scaling the gate to gate dimension is not possible without first reducing or eliminating the diffusion spacer.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of fabricating a semiconductor structure comprises
providing a semiconductor-on-insulator (SOI) substrate having at least an upper semiconductor layer with a device channel thickness of less than 50 nm;
forming at least one patterned gate region on a surface of said SOI substrate;
implanting single, continuous diffusion regions on opposing sides of said at least one patterned gate region; and
forming a stressed liner atop said at least one patterned gate region and said SOI substrate which transfers stress to a device channel located between the single, continuous diffusion regions and underneath the at least one patterned gate region.

2. The method of claim 1 wherein said at least one patterned gate region comprises an n-channel and said stressed liner is under tensile stress.

3. The method of claim 1 wherein said at least one patterned gate region comprises a p-channel and said stressed liner is under compressive stress.

4. The method of claim 1 wherein said at least one patterned gate region comprises at least one n-channel and at least one p-channel, wherein said at least one n-channel is stressed by a first stressed liner that under tensile stress and said at least one p-channel is stressed by a second stressed liner under compressive stress.

5. The method of claim 1 further comprising forming an offset spacer on sidewalls of said at least one patterned gate region, said offset spacer having a thickness from about 3 to about 20 nm.

6. The method of claim 1 further comprising forming an offset spacer on sidewalls of said at least one FET, said offset spacer having a thickness of less than 3 nm.

7. The method of claim 1 further comprising forming a silicided contact located atop said single, continuous diffusion regions.

8. The method of claim 1 wherein said implanting is performed utilizing an extension ion implantation step.

9. The method of claim 1 further comprising forming an isolation region between neighboring pairs of said at least one patterned gate regions such that said neighboring pairs do not share a common single, continuous diffusion region.
